(19) United States
(12) Patent Application Publication
(10) Pub. No.: US 2023/0409176 A1
(43) Pub. Date: Dec. 21, 2023

(54) SAFETY DESIGN SUPPORT SYSTEM AND SAFETY DESIGN SUPPORT METHOD

(71) Applicant: HITACHI, LTD., Chiyoda-ku (JP)

(72) Inventors: Natsumi WATANABE, Tokyo (JP); Masaya ITOH, Tokyo (JP); Hiroyuki YAMADA, Tokyo (JP); Satoshi OTSUKA, Tokyo (JP)

(21) Appl. No.: 18/194,066

(22) Filed: Mar. 31, 2023

(30) Foreign Application Priority Data
May 20, 2022 (JP) 2022-082798

(51) Int. Cl. G06F 3/0484; B60W 50/14; G06F 3/0482

(52) U.S. Cl. CPC G06F 3/0484; B60W 50/14; B60W 60/0015; B60W 2050/146; G06F 3/0482

(57) ABSTRACT

A safety design support system includes a display control unit that causes a display means to display main function design information in which items related to a main function of a product to be designed are hierarchically ordered, and safety design information in which items related to safety design of the product are hierarchically ordered. In accordance with change or addition of an item of the main function design information, the change or addition being made by a user's input operation, the display control unit causes the display means to display instruction information that prompts the user to carry out a next input operation.

### BACKGROUND OF THE INVENTION

### 1. Field of the Invention

The present invention relates to a safety design support system or the like.

### 2. Description of the Related Art

A technique described in Patent Literature 1 is known as a technique for allowing a designer or the like to easily know whether given specifications are satisfied when designing a product. Patent Literature 1 states that when the content of any given item among a plurality of items of product required specifications changes, a product development management system generates a warning mark for the changed item and other items having a tracking relationship with the changed item.

### PRIOR ART DOCUMENT(S)

### Patent Literature(s)

Patent Literature 1: JP2018-109957A

### SUMMARY OF THE INVENTION

According to the technique described in Patent Literature 1, as described above, a warning mark is generated for an item whose content has changed and is generated also for other items having a tracking relationship with the item. However, even in such a case where the warning mark is generated, it is difficult for a user to know what kind of a specific processing the user should execute. The technique is, therefore, yet to be improved.

An object of the present invention is to provide a safety design support system or the like that provides proper support in performing product design.

In order to solve the above problem, a safety design support system according to the present invention includes a display control unit that causes a display means to display main function design information in which items related to a main function of a product to be designed are hierarchically ordered, and safety design information in which items related to safety design of the product are hierarchically ordered. According to a change or addition of an item of the main function design information, the change or addition being based on an input operation by a user, the display control unit causes the display means to display instruction information that leads the user to carry out a next input operation.

The present invention provides a safety design support system or the like that provides proper support in product design.

### BRIEF DESCRIPTION OF THE DRAWINGS

FIG. 1 is a functional block diagram of a computer that executes a program of a safety design support system according to a first embodiment;

FIG. 2 is a functional block diagram of the safety design support system according to the first embodiment;

FIG. 3 is an explanatory diagram of process definition in the safety design support system according to the first embodiment;

FIG. 4 is an example of a display screen related to main function design and safety design in the safety design support system according to the first embodiment;

FIG. 5 is a flowchart showing processing in the safety design support system according to the first embodiment;

FIG. 6 is a functional block diagram of a safety design support system according to a second embodiment;

FIG. 7 is an example of a display screen related to main function design and safety design in the safety design support system according to the second embodiment;

FIG. 8 is a flowchart showing processing in the safety design support system according to the second embodiment;

FIG. 9 is a functional block diagram of a safety design support system according to a third embodiment;

FIG. 10 is an example of a display screen related to main function design and safety design in the safety design support system according to the third embodiment;

FIG. 11 is a flowchart showing processing in the safety design support system according to the third embodiment; and

FIG. 12 is a flowchart showing processing in a safety design support system according to a modification.

### DESCRIPTION OF THE PREFERRED EMBODIMENTS

### First Embodiment

### Configuration of Safety Design Support System

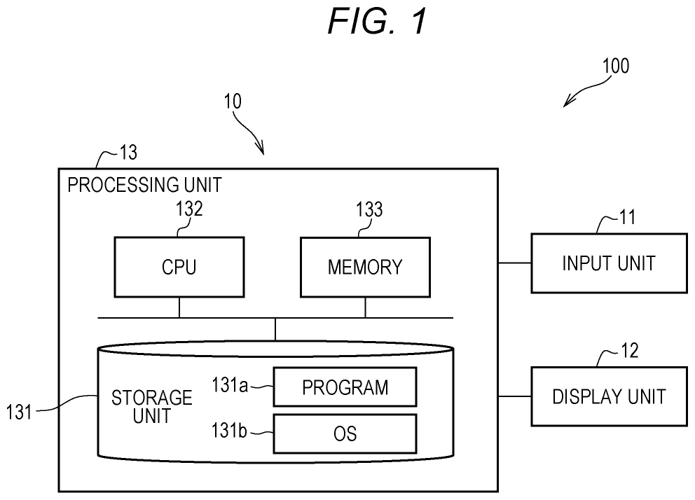

FIG. 1 is a functional block diagram of a computer that executes a program of a safety design support system 100 according to a first embodiment.

The safety design support system 100 is a system that supports a user in performing main function design and safety design of a product (not illustrated). “Main function design” refers to design related to main functions of a product. For example, when the product is an automatic guided vehicle (AGV), design related to its main functions, such as autonomous traveling and article transfer, is the “main function design”. It should be noted that a product does not always have a single main function. It may have a plurality of main functions.

“Safety design” refers to design for ensuring the safety of a product. For example, when the product is an automatic guided vehicle, design related to its safety, such as not coming in contact with a nearby object (including a person) and detecting a problem with an obstacle sensor, etc., of the automatic guided vehicle, is the “safety design”. The “main function design” and the “safety design” are each related to both hardware and software of the product in many cases. They, however, may be related to either the hardware or software only. A designer who performs the “main function design” and a designer who performs the “safety design” may be the same person or may be different persons.

Examples of a product (device) to which the safety design support system 100 is applied include, but not limited to, an automatic guided vehicle, an autonomous forklift, a picking robot, an autonomous robot for inspection, and a construction machine. Other examples of a product to which the safety design support system 100 is applied include, for example, an automobile, a railway vehicle, an aircraft, a ship, an elevator, and an automatic control system of a specific device.

The computer 10 shown in FIG. 1 includes an input unit 11, a display unit 12 (display means), and a processing unit 13. The input unit 11 is, for example, a keyboard or a mouse operated by a user. The display unit 12 is, for example, a display. In addition to its display function, the display unit 12 may have a data input function as well, as in the case of a touch panel display. The display unit 12 may be further provided with a speaker or the like (not illustrated) that outputs a given sound.

The processing unit 13 includes a storage unit 131, a central processing unit (CPU) 132, and a memory 133. For example, a hard disk drive (HDD) is used as the storage unit 131. As shown in FIG. 1, a given program 131a and an operating system (OS) 131b are stored in the storage unit 131 in advance. The CPU 132 reads the program stored in the storage unit 131, loads the program onto a memory 133, and executes given processing. The memory 133 is used to load the program 131a thereon, and includes, for example, a random access memory (RAM) and a register. Based on the user's operation on the input unit 11, the processing unit 13 executes a given processing and causes the display unit 12 to display a result of the processing in a given manner.

The result of processing by the computer 10 may be transmitted to an information terminal (not illustrated) of the user via a network (not illustrated) and displayed on the information terminal in a given manner. A given program may be executed in the information terminal of the user. As such an information terminal, a smartphone, a mobile phone, a tablet, a personal computer, a wearable terminal, or the like is used. The safety design support system 100, as shown in FIG. 1, may be composed of one computer 10 or may be composed of a plurality of computers (not illustrated) interconnected in a given manner via a signal line or a network.

Users who uses the computer 10 include, for example, a designer involved in at least either main function design or safety design of a product, a person involved in a product development plan, a development process manager, and a product safety test implementer. As the structure and system of a product become more complicated, the number of items of specifications related to functional and safety aspects of the product increases and the number of people involved in product design increases as well.

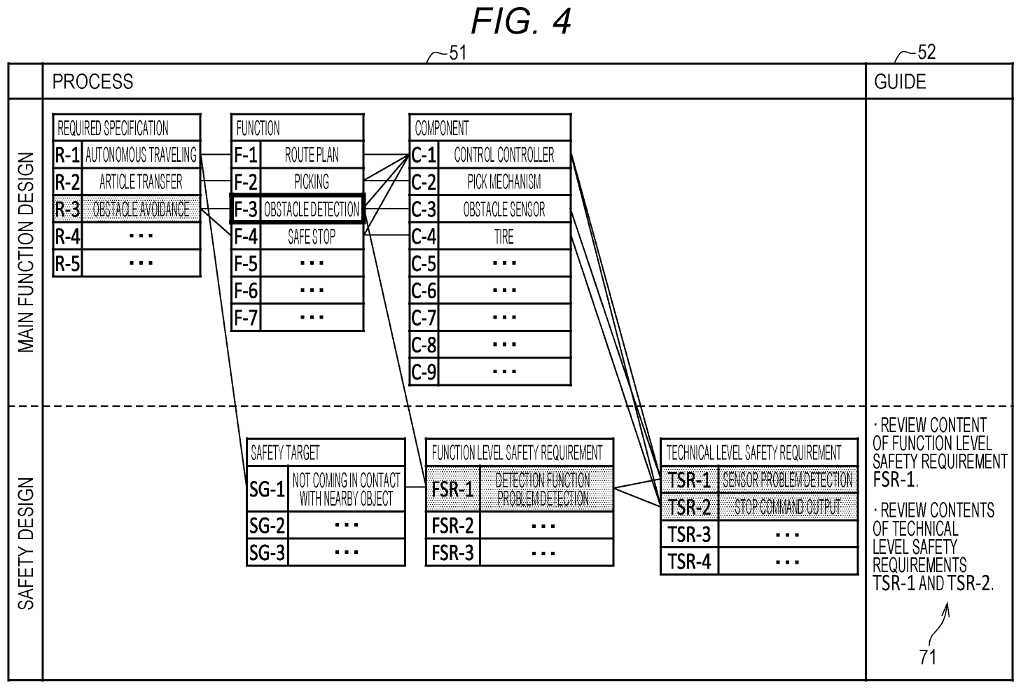

There may be, therefore, a case where the safety design support system 100 is used as a tool a plurality of users use to share data on functional and safety specifications of a product (see FIG. 4). In such a case, as described above, individual information terminals (not illustrated) of the users may be connected to the computer 10 (e.g., a server) via the network (not illustrated).

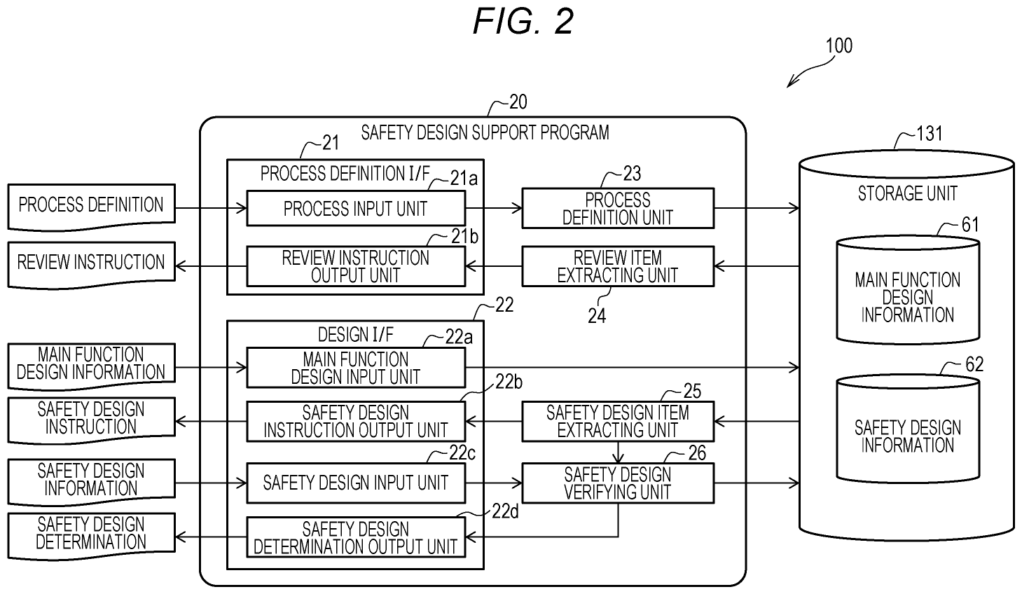

FIG. 2 is a functional block diagram of the safety design support system 100.

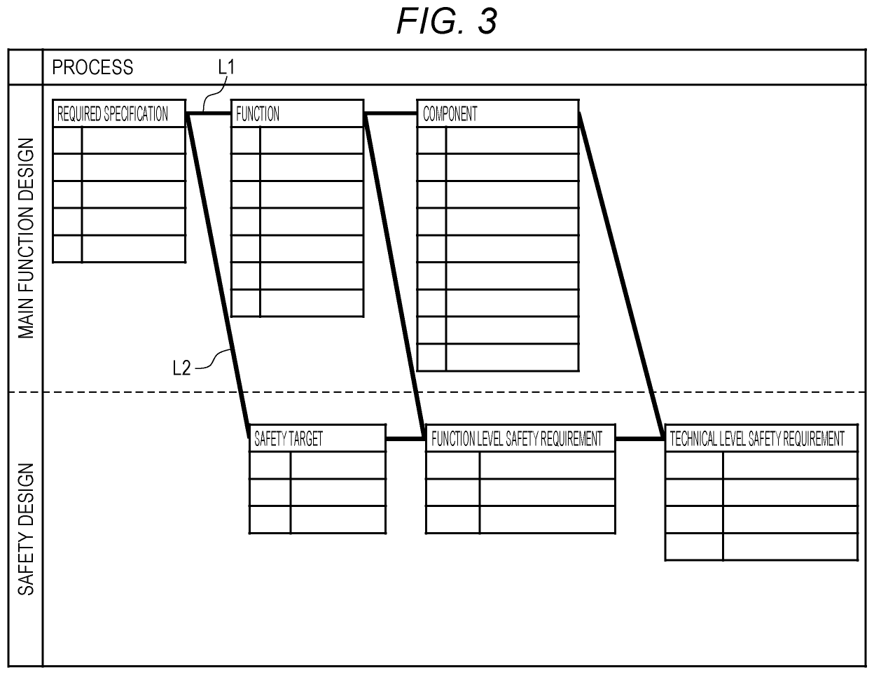

A safety design support program 20 executed by the safety design support system 100 includes a process definition interface 21, a design interface 22, a process definition unit 23, a review item extracting unit 24, a safety design item extracting unit 25, and a safety design verifying unit 26, which are functional constituent elements of the safety design support program 20. The process definition interface 21 inputs and outputs data on a process of main function design and safety design. “Process” means a given category (such as “required specification” in FIG. 3) to which data hierarchically ordered in main function design or safety design belongs.

As shown in FIG. 2, the process definition interface 21 includes a process input unit 21a and a review instruction output unit 21b. The process input unit 21a receives input of process definition data by the user's operation on the input unit 11 (see FIG. 1). The process definition unit 23 stores process definition data received by the process input unit 21a in the storage unit 131. Other constituent elements, such as the review item extracting unit 24 and the review instruction output unit 21b, will be described later.

FIG. 3 is an explanatory diagram of a process definition in the safety design support system.

In the example of FIG. 3, “required specification”, “function”, and “component” are defined (set) as processes of main function design of a given product. “Required specification” is one or a plurality of main functions required for a product (see also FIG. 4). “Function” is a specific function that a product should have in order to satisfy a given “required specification” (see also FIG. 4). “Component” is a constituent element that a product should have in order to perform a given “function” (see also FIG. 4).

In the example of FIG. 3, a process of “required specification” (a block of large framework that includes a plurality of item columns) and a process of “function” are connected by a straight line L1 (a thick solid line in FIG. 3). The straight line L1 indicates that a so-called tracking relationship (dependency relationship) may exist between a given item included in the “required specification” and a given item included in the “function”. In a specific example in which a target product is an automatic guided vehicle, when a function of “route planning” (see F-1 in FIG. 4) is required to satisfy a required specification of “autonomous traveling” (see R-1 in FIG. 4), a tracking relationship exists between an item of “autonomous traveling” and an item of “route planning”. The straight line L1 shown in FIG. 3 indicates that such a tracking relationship (dependency relationship) may exist between an item in the “required specification” and an item in the “function”. Such process definition data may be set in advance as initial setting or may be set by the user's operation on the input unit 11 (see FIG. 1).

In the example of FIG. 3, the processes of “required specification”, “function”, and “component” are hierarchically ordered and are sequentially connected by straight lines (straight lines each indicating that a tracking relationship may exist). As a hierarchy related to main function design, the “required specification” is ranked at the top, and the “function” and “component” are ranked below the “required specification” in descending order.

In addition, as processes of product safety design, “safety target”, “function level safety requirement”, and “technical level safety requirement” are defined (set). “Safety target” refers to a given target concerning the safety of a product (see also FIG. 4). “Function level safety requirement” refers to a function that a product should have in order to meet a given “safety target” (see also FIG. 4). “Technical level safety requirement” refers to a technical matter required for ensuring that a product meets a given “function level safety requirement” (see also FIG. 4).

In the example of FIG. 3, the “safety target”, “function level safety requirement”, and “technical level safety requirement” are hierarchically ordered and are sequentially connected by straight lines (straight lines each indicating that a tracking relationship may exist). As a hierarchy related to safety design, the “safety target” is ranked at the top, and the “function level safety requirement” and “technical level safety requirement” are ranked below the “safety target” in descending order. In addition, processes of main function design and processes of safety design are also connected to each other in a given manner by straight lines. For example, the process of “required specification” and the process of “safety target” are connected to each other by a straight line L2. A display screen where such a data structure of large framework is set may be the same as a display screen shown in FIG. 3 or may be a prescribed setting screen different from the display screen of FIG. 3.

Along a process defined by the process definition interface 21, the design interface 22 shown in FIG. 2 inputs and outputs data related to items of main function design and safety design. As shown in FIG. 2, the design interface 22 includes a main function design input unit 22a, a safety design instruction output unit 22b, a safety design input unit 22c, and a safety design determination output unit 22d. The main function design input unit 22a receives input of the main function design information 61 by the user's operation on the input unit 11 (see FIG. 1).

FIG. 4 is an example of a display screen related to main function design and safety design in the safety design support system.

The example of FIG. 4 is a case where a product to be designed is an automatic guided vehicle. As shown in FIG. 4, on the display screen of the display unit 12 (see FIG. 1), a “process” display area 51 and a “guide” display area 52 are displayed on the left and right sides adjacent to each other. In the “process” display area 51, items of main function design are displayed on the upper side while items of safety design are displayed on the lower side. In the “process” display area 51, in addition to the items of main function design and the safety design, a plurality of straight lines indicating tracking relationships (dependency relationships) between items are also displayed. This allows the user to visually confirm tracking relationships between items. By visually following the straight lines indicating the tracking relationships, the user is able to know whether safety aspects of the product are examined without omissions.

Data of the items and tracking relationships shown in FIG. 3 may be created before the product is actually designed or may be created in the process of designing the product (the process including a change or addition of an item). In the guide display area 52, for example, when an item of main function design is changed or added, a matter the user should consider in safety design is displayed.

The main function design input unit 22a shown in FIG. 2 has a function of receiving an input of the main function design information 61. In other words, by the user's operation on the input unit 11 (see FIG. 1), the main function design input unit 22a accepts addition or change of an item (main function design information 61) in each process, such as “required specification”, “function”, and “component” in main function design (see FIG. 4). For example, a case is assumed where, by the user's operation on the input unit 11 (see FIG. 1), an item (text data) “obstacle detection” (see F-3 in FIG. 4) is newly set in the process of “function”. When the item of “obstacle detection” is added in this manner, a tracking relationship between the item of “obstacle detection” and other items is usually inputted as well, based on a judgement made by the user.

More specifically, because a function of “obstacle detection” is a function for satisfying a required specification of “obstacle avoidance” (see R-3 in FIG. 4), a tracking relationship (dependency relationship) exists between the “obstacle detection” and the “obstacle avoidance”. The user, therefore, selects the “obstacle avoidance” as one of items having tracking relationships with the “obstacle detection”. Selection methods in this case are as follows: the user operates the input unit 11 (see FIG. 1) in a given manner and clicks the corresponding item (e.g., the item of “obstacle avoidance”) on the display screen or switches to a detailed item input screen and selects the corresponding item from a pull-down list.

In addition to a tracking relationship with an item ranked higher in hierarchy than the item of “obstacle detection” (e.g., “obstacle avoidance” in FIG. 4), a tracking relationship with an item ranked lower in hierarchy than the same (e.g., “control controller” in FIG. 4) or with a given item of safety design (e.g., “detection function problem detection” in FIG. 4) may also be inputted. In a stage of process definition (see FIG. 3), actual tracking relationships are set between items in different processes (e.g., the processes of “required specification” and “function” in FIG. 3) that are set as processes between which a tracking relationship may exist.

A “display control unit” causes the display unit 12 (display means) to display the main function design information 61, in which items related to main functions of the product to be designed are hierarchically ordered, and safety design information 62, in which items related to safety design of the product are hierarchically ordered. This display control unit includes the process definition interface 21 and the design interface 22 that are shown in FIG. 2.

When an item related to main function design is added or changed, the main function design input unit 22a (see FIG. 2) executes the next processing. Specifically, in addition to given text data (e.g., text data “obstacle detection”) input by the user, the main function design input unit 22a stores a process to which an item of the text data belongs (e.g., the process of “function”) and data indicating a tracking relationship between the item and a different item, in the storage unit 131 (see FIG. 2), as the main function design information 61.

The safety design item extracting unit 25 shown in FIG. 2 extracts an item of safety design to be changed or added, based on the content of input to the main function design input unit 22a. For example, a case is assumed where the item of “obstacle detection” shown in FIG. 4 is changed in a given manner by the user's operation on the input unit 11 (see FIG. 1). In such a case, the safety design item extracting unit 25 extracts an item of “detection function problem detection” having a tracking relationship with the “obstacle detection” in safety design, and further extracts items of “sensor problem detection” and “stop command output” each having a tracking relationship with the “detection function problem detection”.

In other words, when the item of “obstacle detection”, which is one of the main function design information 61, is changed, the items of “detection function problem detection”, “sensor problem detection”, and “stop command output” each having a direct or indirect tracking relationship with the “obstacle detection” are extracted as items to be reviewed by the user. It should be noted that when a direct tracking relationship exists between given items of “α” and “β” and exists also between “β” and “γ”, an indirect tracking relationship exists between “α” and “γ”.

The safety design instruction output unit 22b shown in FIG. 2 outputs given instruction information on safety design, based on an item extracted by the safety design item extracting unit 25. Specifically, when an item of the main function design information 61 is changed or added, the safety design instruction output unit 22b (display control unit) causes the display unit 12 (display means: see FIG. 1) to display instruction information instructing the user to review an item of the safety design information 62, the item having a direct or indirect tracking relationship with the changed or added item of the main function design information 61.

For example, when text data of the item of “obstacle detection” shown in FIG. 4 is changed in a given manner, the safety design instruction output unit 22b executes the next processing. Specifically, the safety design instruction output unit 22b displays a message “Review the contents of technical level safety requirements TSR-1 and TSR-2.” as well as a message “Review the content of function level safety requirement FSR-1.” in the guide display area 52, as instruction information 71 on safety design. FSR-1, TSR-1, and TSR-2, which serve as identification information, are associated with “detection function problem detection”, “sensor problem detection”, and “stop command output” in this order, and are displayed in the process display area 51.

In this manner, according to a change or addition of an item of the main function design information 61, the change or addition being based on the user's input operation, the safety design instruction output unit 22b (display control unit: see FIG. 2) causes the display unit 12 (display means: see FIG. 1) to display the instruction information 71 that prompts the use to carry out the next input operation. As a result, items of safety design to be reviewed are indicated specifically according to the content of main function design changed by the user's input operation. After changing main function design, therefore, the user is able to review safety design efficiently without omission. It should be noted that, as shown in the example of FIG. 4, a case of pieces of instruction information 71 being displayed in the guide display area 52 is included in the concept of “prompting the user to carry out the next input operation”.

The safety design instruction output unit 22b (see FIG. 2) may display each item having a direct or indirect tracking relationship with the item of “obstacle detection” in a highlighted form (in a dotted pattern in FIG. 4). Further, a straight line indicating a tracking relationship between the item of “obstacle detection” and a different item may be displayed as a line different in a color, thickness, or type from other straight lines. This allows the user to know at a glance which item of the safety design information 62 should be reviewed in accordance with addition or change of an item of the main function design information 61.

Items of the main function design information 61 and items of the safety design information 62 may include items associated with the values of design work scales. “Work scale” refers to data including values indicating the number of days and man-hours (workload units) that are required for design work on a given item (e.g., “sensor problem detection” in FIG. 4), and is set by the user's operation on the input unit 11 (see FIG. 1). When a plurality of items having a direct or indirect tracking relationship with a changed or added item of the main function design information 61 are present, the safety design instruction output unit 22b (display control unit: see FIG. 2) may cause the display unit 12 (display means: see FIG. 1) to display the instruction information such that the items are reviewed in descending order of a work scale value. As a result, among the items need to be examined for the need of change or addition, an item with a larger design work scale is examined in priority for the need of change or addition. As a result, the user is able to efficiently carry out a safety design review that is required as a result of a change or addition of main function design.

For example, when the safety design instruction output unit 22b (see FIG. 2) displays given instruction information in the guide display area 52 (see FIG. 4), an order (order based on work scales) the user should examine may be indicated by numbers, etc. In addition, the safety design instruction output unit 22b (see FIG. 2) may display the given instruction information in the order based on the work scales in accordance with the progress status of item review work by the user.

Further, when a plurality of items having a direct or indirect tracking relationship with a changed or added item of the main function design information 61 are present, the safety design instruction output unit 22b (display control unit: see FIG. 2) may cause the display unit 12 (display means: see FIG. 1) to display the instruction information such that the items are reviewed in descending order of a number of tracking relationships with other items. As a result, among the items need to be examined for the need of change or addition, an item having a greater number of tracking relationships with other items is examined in priority for the need of change or addition. This processing also allows the user to efficiently carry out the safety design review.

The safety design input unit 22c shown in FIG. 2 receives input of the safety design information 62 (change or addition of an item of safety design) by the user's operation on the input unit 11 (see FIG. 1). As described above, when a matter the user should examine as a result of a change or addition of an item of main function design is present, the given instruction information 71 is displayed in the guide display area 52 (see FIG. 4). Based on this instruction information 71, the user inputs the safety design information 62. In addition to text data of items of safety design (e.g., text data “detection function problem detection” in FIG. 4), the safety design information 62 includes also a process to which the item belongs (e.g., “function level safety requirement” in FIG. 4) and data indicating a tracking relationship between the item and a different item.

The safety design verifying unit 26 shown in FIG. 2 verifies whether items extracted by the safety design item extracting unit 25 has been reviewed without omission, based on the safety design information 62 received by the safety design input unit 22c.

The safety design determination output unit 22d shown in FIG. 2 causes the display unit 12 (see FIG. 1) to display a verification result given by the safety design verifying unit 26. Specifically, when given instruction information is displayed and then items of the safety design information 62 are inputted by the user's input operation, the safety design determination output unit 22d (display control unit) executes the next processing. Specifically, when an item having not been changed or added remains among items of the safety design information 62 that are to be reviewed, the safety design determination output unit 22d causes the display unit 12 (display means: see FIG. 1) to display a predetermined message. As a result, when having changed or added an item of main function design, the user is able to check whether the user has reviewed the safety design information 62 without omission.

For example, a case is assumed where the safety design item extracting unit 25 (see FIG. 2) has extracted three items of “detection function problem detection”, “sensor problem detection”, and “stop command output” as a result of a change of the item of “obstacle detection” shown in FIG. 4. In such a case, the safety design verifying unit 26 (see FIG. 2) determines whether the above three items are included in the safety design information 62 newly changed by the user's input operation. Among the above three items, for example, when the item of “stop command output” is not changed, the safety design determination output unit 22d (see FIG. 2) causes the display unit to display a message “technical level safety requirement TSR-2 ‘stop command output’ has not been updated” in the guide display area 52. In this manner, by providing the system with a check function for safety design, the user is able to carry out a safety design review without omission, the safety design review being required as a result of a change of main function design.

When a given item does not need to be changed in particular, the user may select a button (not illustrated), such as a “No change” button or an “OK” button, linked to the item. When the “No change” button or “OK” button is selected for the given item, the safety design verifying unit 26 determines that the item has been examined for the need of review.

When a process is changed or added in a situation where each item of processes has already been inputted using the design interface 22, the review item extracting unit 24 shown in FIG. 2 extracts items of main function design and safety design that need to be reviewed. For example, when a new process is added between the “function” and the “component” shown in FIG. 4, the review item extracting unit 24 extracts an item required to be reviewed as a result of addition of the new process.

The review instruction output unit 21b shown in FIG. 2 causes the display unit 12 (see FIG. 1) to display the item extracted by the review item extracting unit 24, as an item to be reviewed. In this manner, even when a process is added in a situation where each item of processes has already been inputted, an item the user should review is displayed. This prevents a delay in design work.

The review item extracting unit 24 may allow the user to examine an item with a larger work scale of design work indicated by the item in priority over other items, for the need of change, etc., the item being among a plurality of items to be examined for the need of change, etc., in the same manner as the safety design item extracting unit 25 (see FIG. 2) does. The review item extracting unit 24 may allow the user to examine an item having a greater number of tracking relationships with other items in priority for the need of change, etc. The user is thus able to proceed with review work efficiently.

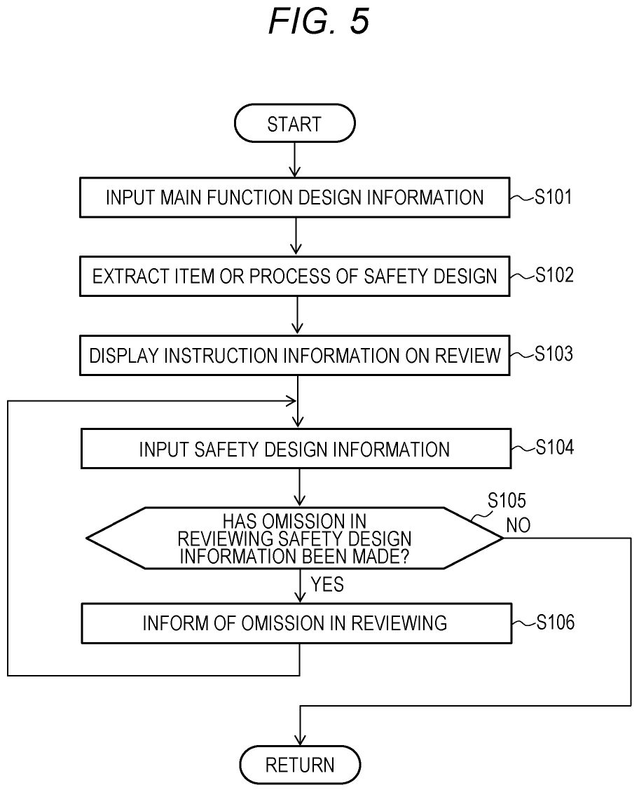

FIG. 5 is a flowchart showing processing in the safety design support system (see FIG. 2 also when needed).

It is assumed that at the point of “START” in FIG. 5, each process (see FIG. 3) is already set and the main function design information 61 and safety design information 62 as prescribed information are displayed on the display unit 12 (see FIG. 1) (first display processing). A case where an item of main function design is newly added will be described below as an example. The description applies also to a case where an item of main function design is changed.

At step S101, the safety design support system 100 causes the main function design input unit 22a to receive input of the main function design information 61. For example, when a given item is added to the process of “function” (see FIG. 4) of main function design, the main function design input unit 22a stores text data of the added item and data indicating the process (“function”) to which the item belongs and a tracking relationship between the item and a different item, in the storage unit 131, as the main function design information 61.

At step S102, the safety design support system 100 causes the safety design item extracting unit 25 to extract an item or process of safety design. For example, when a given item is newly added to the process of “function” (see FIG. 4), the safety design item extracting unit 25 first refers to process definition data (see FIG. 3). As shown in FIG. 3, items that may have a direct or indirect tracking relationship with an item of the “function” in safety design are items of “function level safety requirement” and “technology level safety requirement”.

When an item belonging to the “function” is newly added, therefore, a new item may need to be set in the “function level safety requirement” or the “technical level safety requirement” of safety design. The safety design item extracting unit 25, therefore, extracts the “function level safety requirement” and the “technical level safety requirement”, as processes to be examined for the need of new item setting. As described above, when a given item (e.g., “obstacle detection” in FIG. 4) is changed, a given item having a direct or indirect tracking relationship with the changed item is extracted.

At step S103, the safety design support system 100 causes the safety design instruction output unit 22b to display given instruction information on safety design review. Specifically, in accordance with change or addition of an item of the main function design information 61, the change or addition being based on the user's input operation, the safety design instruction output unit 22b causes the display unit 12 (display means: see FIG. 1) to display the instruction information that prompts the user to carry out the next input operation (second display processing). For example, when the “function level safety requirement” (see FIG. 4) is extracted as a process to be examined for addition of an item (S102), the safety design instruction output unit 22b causes the display unit 12 to display an instruction information “Consider adding an item to the function level safety requirement” in the guide display area 52.

At step S104, the safety design support system 100 causes the safety design input unit 22c to receive input of the safety design information 62. For example, a given item of the safety design information 62 is added or changed in accordance with the instruction information displayed at step S103.

At step S105, the safety design support system 100 causes the safety design verifying unit 26 to determine whether omission in reviewing the safety design information 62 is made. It is assumed, for example, that a given item is added to the process of “function” (S101) and the “function level safety requirement” and “technology level safety requirement” are extracted as processes to be examined for the need of new item setting (S102). In such a case, at step S105, the safety design verifying unit 26 determines whether a new item has been set in each of the “function level safety requirement” and the “technical level safety requirement”.

When it is determined at step 5105 that omission in reviewing the safety design information 62 is made (S105: Yes), the safety design support system 100 proceeds to step S106.

At step S106, the safety design support system 100 causes the safety design determination output unit 22d to inform of omission in reviewing the safety design information 62. For example, the safety design determination output unit 22d causes the display unit to display a message “'function level safety requirement' item associated with function F-3 ‘obstacle detection’ is not created” in the guide display area 52 (see FIG. 4). After executing step S106, the safety design support system 100 returns to step S104.

When it is determined at step S105 that omission in reviewing the safety design information 62 is not made (S105: NO), the safety design support system 100 returns to “START” (RETURN). When omission in reviewing the safety design information 62 is not made (S105: NO), a message informing of no omission of input of the safety design information 62 may be displayed. A series of steps shown in FIG. 5 are repeated every time change or addition of the main function design information 61 is made.

### Effects

According to the first embodiment, every time the main function design information 61 is changed or added, the given instruction information is displayed to prompt the user to carry out the next input operation. This allows the user to proceed with main function design and safety design of the product at the same time. If main function design and safety design are each carried out independently without taking account of a dependency relationship between main function design and safety design, it raises a possibility that unexpected rework or correction may arises to increase development man-hours. According to the first embodiment, in contrast, every time the main function design information 61 is changed or added, an item or the like the user should review is indicated, based on a tracking relationship between items. As a result, the user is able to efficiently proceed with product design work.

According to the first embodiment, when an item of the main function design information 61 is changed or added, an item of the safety design information 62 the user should review is presented specifically. The user is, therefore, able to know properly which item of the safety design information 62 the user should change.

According to the first embodiment, for example, when an item of the main function design information 61 is added, a process to be examined next for addition of an item is presented. This prevents omission in reviewing the safety design information 62. In this manner, according to the first embodiment, the safety design support system 100 that provides proper support in product design can be provided.

### Second Embodiment

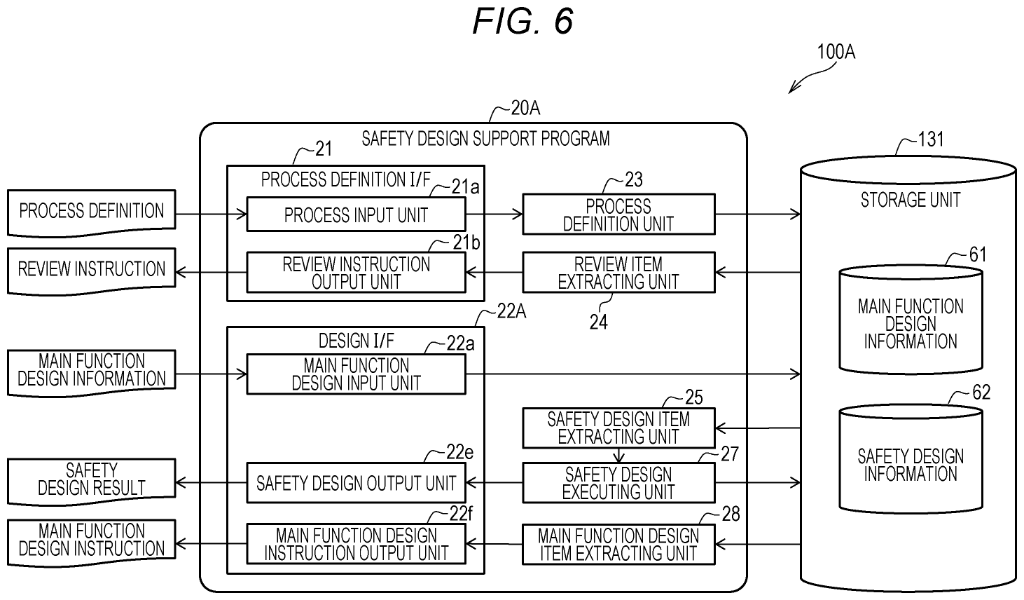

A second embodiment is different from the first embodiment in that the safety design support system includes a safety design executing unit 27 (see FIG. 6) that creates the safety design information 62, based on the main function design information 61. The second embodiment is different from the first embodiment in that the main function design information 61 that needs to be reviewed is indicated, based on the safety design information 62 created by the safety design executing unit 27 (see FIG. 6). The second embodiment is the same as the first embodiment in other respects. Respects different from those of the first embodiment will therefore be described and the same respects as those of the first embodiment will not be described.

FIG. 6 is a functional block diagram of a safety design support system 100A according to a second embodiment.

A safety design support program 20A shown in FIG. 6 includes the process definition interface 21 (display control unit), a design interface 22 A (display control unit), the process definition unit 23, the review item extracting unit 24, the safety design item extracting unit 25, the safety design executing unit 27, and a main function design item extracting unit 28, which are functional constituent elements. The design interface 22A includes the main function design input unit 22a, a safety design output unit 22e, and a main function design instruction output unit 22f.

The main function design input unit 22a has a function of receiving input of the main function design information 61.

The safety design item extracting unit 25 extracts an item of safety design to be changed or added, based on a tracking relationship between the item with an item inputted on the main function design input unit 22a. Because processing by the main function design input unit 22a and the safety design item extracting unit 25 is the same as that of the first embodiment, detailed description of the processing will be omitted.

The safety design executing unit 27 creates the safety design information 62, based on the main function design information 61. In other words, the safety design executing unit 27 executes a safety analysis and safety function design, based on items extracted by the safety design item extracting unit 25. As processing by the safety design executing unit 27, for example, an analysis, such as fault tree analysis (FTA) or failure mode and effect analysis (FMEA) using artificial intelligence (AI), may be carried out. In addition, data of products developed in the past may be used on a necessary basis.

The safety design output unit 22e causes the display unit 12 (see FIG. 1) to display a result of processing by the safety design executing unit 27 in a given manner. Providing the safety design executing unit 27 and the safety design output unit 22e in this manner makes it unnecessary for the user to input all items of the safety design information 62. This reduces workload of the user and reduces a time required for processing as well.

The main function design item extracting unit 28 extracts an item of main function design that needs to be reviewed, based on the safety design information 62 created (or updated) by the safety design executing unit 27. The main function design instruction output unit 22f causes the display unit to display given instruction information on an item of main function design extracted by the main function design item extracting unit 28. Details of processing by the main function design item extracting unit 28 and the main function design instruction output unit 22f will be described later.

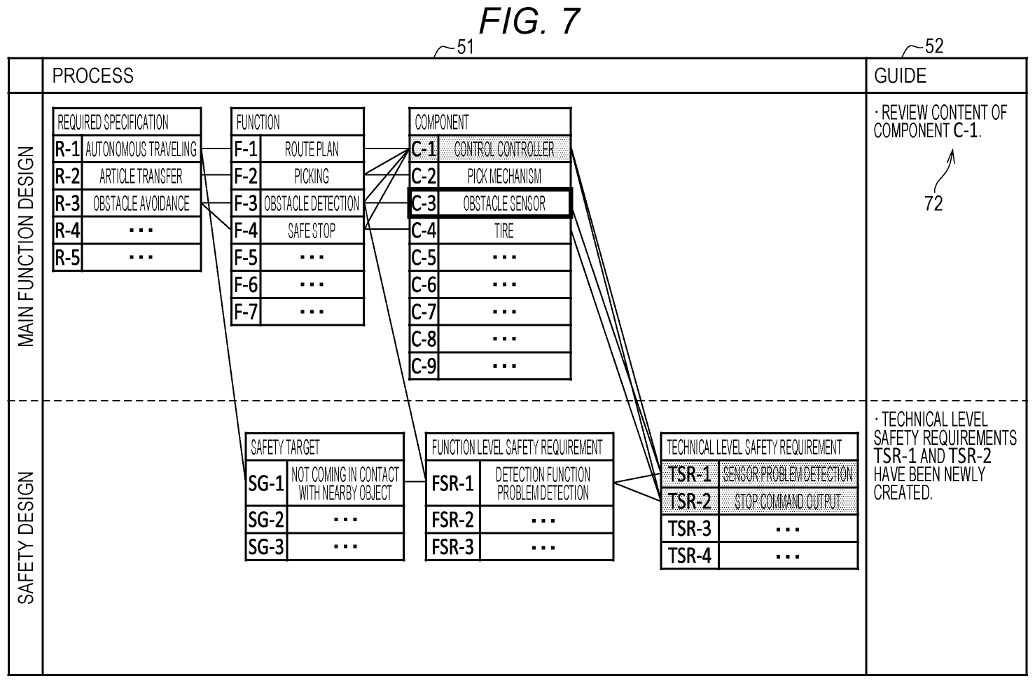

FIG. 7 is an example of a display screen related to main function design and safety design in the safety design support system (see also Fig, 6 when necessary).

First, items of main function design are inputted one by one by the user's operation on the input unit 11 (see FIG. 1). When items of main function design are inputted in this manner, the safety design executing unit 27 (see FIG. 6) adds or changes items of safety design in accordance with the inputted items (which means that the safety design information 62 is automatically created). The safety design information 62 created in this manner is displayed in a given manner in a safety design column in the process display area 51.

For example, a case is assumed where based on the user's operation on the input unit 11 (see FIG. 1), the item of “obstacle sensor” is newly created as one of items in the “component”. In this case, based on an analysis by the safety design executing unit 27 (see FIG. 6), the items of “sensor problem detection” and “stop command output” are created as items included in the “technical level safety requirement”. At the same time, tracking relationships between the items of “sensor problem detection” and “stop command output” and items in main function design, such as “control controller”, are set by the safety design executing unit 27 (see FIG. 6).

In the example of FIG. 7, a predetermined message indicating that individual items of safety design have been newly created (or changed) is displayed in the guide display area 52. The user is thus able to easily understand that as a result of addition of the item of “obstacle sensor” by the user's input operation, individual items of “sensor problem detection” and “stop command output” have been newly created as items of safety design.

The main function design item extracting unit 28 extracts the item of “control controller” as the main function design information 61 that has a tracking relationship with the items of “sensor problem detection” and “stop command output”. When an item of the main function design information 61 is changed or added, the main function design instruction output unit 22f (display control unit: see FIG. 6) executes the following processing. Specifically, the main function design instruction output unit 22f causes the display unit 12 (display means: see FIG. 1) to display instruction information that instructs the user to review an item of the main function design information 61 that has a direct or indirect tracking relationship with an item of the safety design information 62 that has been newly created as a result of change or addition of an item. In the example of FIG. 7, a message “Review the content of component C-1.” is displayed as the instruction information 72. By confirming this message, the user is able to proceed with designing of the “control controller” in such a way as to satisfy the “technical level safety requirement”, such as the “sensor problem detection” and the “stop command output”.

In this manner, according to the second embodiment, the safety design information 62 is created as a result of input of the main function design information 61 by the user, and the given instruction information is displayed for the main function design information 61 that needs to be reviewed. Results of safety design are, therefore, reflected in main function design one after another. This allows the user to proceed with product design efficiently. A case of finding the necessity of modifying the main function design of the product in a later stage is, therefore, prevented, which allows the user to proceed with product design efficiently.

It is preferable that the main function design instruction output unit 22f (see FIG. 6) cause the display unit to display given instruction information so that a plurality of items the user should review are reviewed in descending order of a design work scale. This allows the user to efficiently make a review that is required as a result of change or addition of main function design.

The main function design instruction output unit 22f (see FIG. 6) may cause the display unit to display given instruction information so that items are reviewed in descending order of a number of tracking relationships with other items. This makes the user's review work efficient.

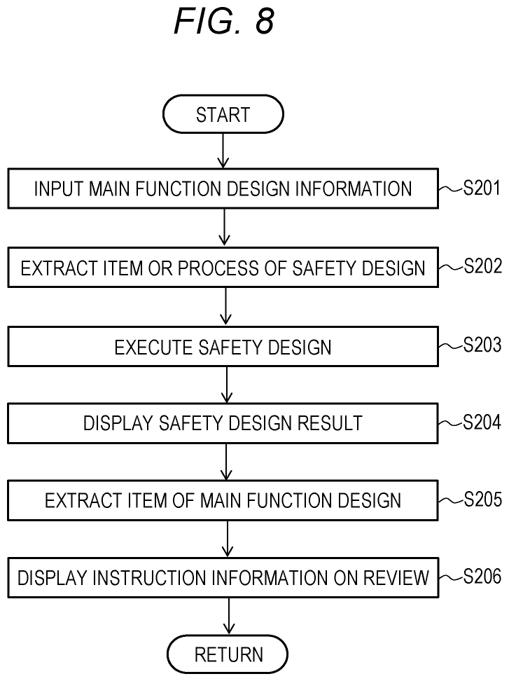

FIG. 8 is a flowchart showing processing in the safety design support system (see FIG. 6 when necessary).

It is assumed that at the point of “START” in FIG. 8, each process is already defined (set). At step S201, the safety design support system 100A causes the main function design input unit 22a to receive input of the main function design information 61. In the example of FIG. 7, an item of “obstacle sensor” is added to the process of “component”.

At step S202, the safety design support system 100A causes the safety design item extracting unit 25 to extract an item or process of safety design. Specifically, the safety design item extracting unit 25 extracts an item, etc., of safety design that is to be changed or added, based on a tracking relationship with the item of the main function design information 61 that has been inputted at step S201. In the example of FIG. 7, an item of safety design that may have a tracking relationship with an item in the “component” is an item in the “technical level safety requirement” (see also process definition of FIG. 3). In such a case, the safety design item extracting unit 25 extracts the “technical level safety requirement” as a process to which an item of safety design is to be added.

When a given item (e.g., “obstacle sensor” shown in FIG. 7) is changed, a given item having a tracking relationship with the changed item is extracted.

Subsequently, at step S203, the safety design support system 100A causes the safety design executing unit 27 to execute safety design. Specifically, the safety design executing unit 27 specifies the specific content of the item or process of safety design that has been extracted at step S202.

At step S204, the safety design support system 100A causes the safety design output unit 22e to display a safety design result.

At step S205, the safety design support system 100A causes the main function design item extracting unit 28 to extract an item of main function design that needs to be reviewed. Specifically, the main function design item extracting unit 28 extracts an item of main function design that has a tracking relationship with an added or changed item of safety design.

At step S206, the safety design support system 100A causes the main function design instruction output unit 22f to display instruction information on review of the item of main function design. After executing step S206, the safety design support system 100A returns to “START” (RETURN). A series of steps shown in FIG. 8 are repeated every time change or addition of the main function design information 61 is made.

After the instruction information is displayed at step S206, the design interface 22A (see FIG. 6) may determine whether all items of main function design that need to be reviewed have been reviewed. When an item not reviewed by the user remains, the design interface 22A may cause the display unit to display a predetermined message. This prevents omission in review by the user. When a given item does not need to be changed in particular, the user may select a button (not illustrated), such as a “No change” button or an “OK” button, linked to the item.

### Effects

According to the second embodiment, when the main function design information 61 is inputted by the user's input operation, the safety design executing unit 27 (see FIG. 6) creates the safety design information 62. This reduces work the user needs to carry to create the safety design information 62.

In addition, an item of the main function design information 61 that the user should review is displayed, based on a tracking relationship between the item and an item of the safety design information 62 that has been newly created. Results of safety design are, therefore, reflected in main function design one after another. This allows the user to proceed with product design efficiently.

### Third Embodiment

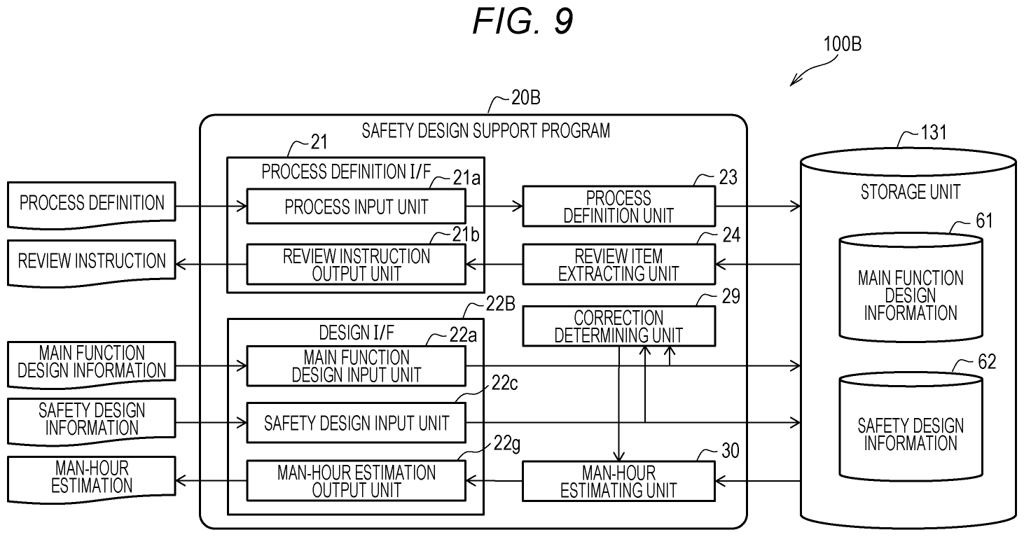

A third embodiment is different from the first embodiment in that the safety design support system includes a man-hour estimating unit 30 (see FIG. 9) that estimates man-hours required for reviewing or correcting product design as a result of addition or change of main function design or safety design. The second embodiment is the same as the first embodiment in other respects.

Respects different from those of the first embodiment will therefore be described and the same respects as those of the first embodiment will not be described.

FIG. 9 is a functional block diagram of a safety design support system 100B according to the third embodiment.

A safety design support program 20B shown in FIG. 9 includes the process definition interface 21, a design interface 22B, the process definition unit 23, the review item extracting unit 24, a correction determining unit 29, and the man-hour estimating unit 30, which are functional constituent elements. In addition, the design interface 22B includes the main function design input unit 22a, the safety design input unit 22c, and a man-hour estimation output unit 22g.

The main function design input unit 22a and the safety design input unit 22c are the same as those of the first embodiment (see FIG. 2). Specifically, the main function design input unit 22a receives input of the main function design information 61. The safety design input unit 22c receives input of the safety design information 62.

The correction determining unit 29 determines whether correction of the main function design information 61 or the safety design information 62 (change or addition of an item) has been made.

The man-hour estimating unit 30 estimates man-hours required for reviewing or correcting product design, based on a determination result from the correction determining unit 29. As a method of estimating such man-hours, for example, the sum of work scales of other items having a tracking relationship with an item changed or added may be used. As described in the first embodiment, a work scale refers to data including values indicating the number of days and man-hours that are required for design work of a given item.

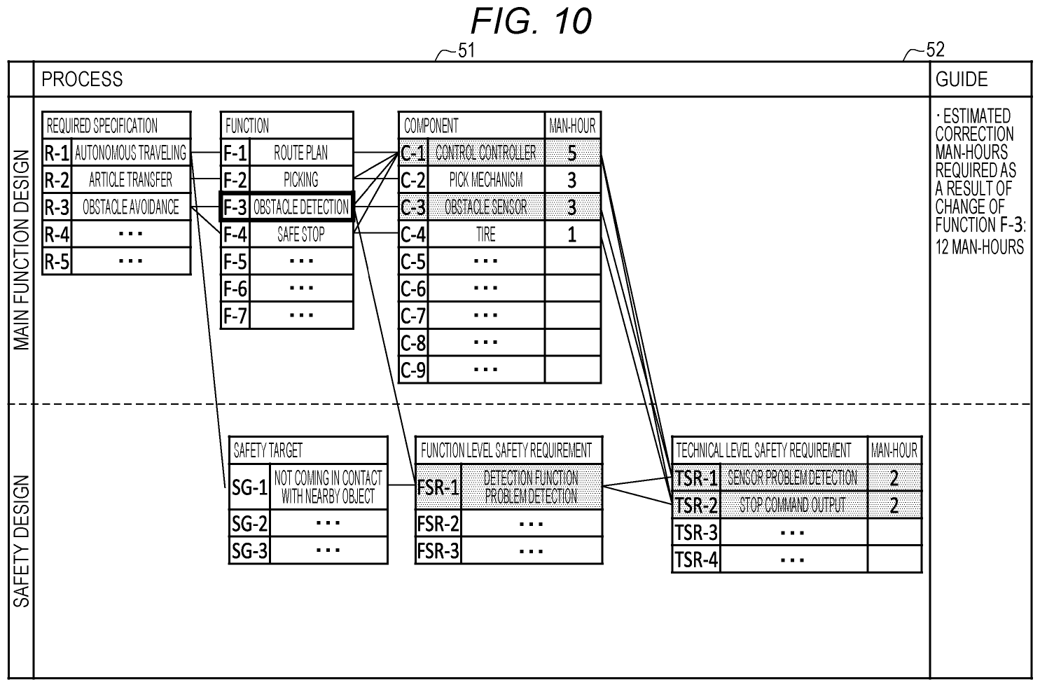

The man-hour estimation output unit 22g shown in FIG. 9 displays an estimation result from the man-hour estimating unit 30. For example, the man-hour estimation output unit 22g displays man-hours required for reviewing the product design as a result of addition or change of a given item, in the guide display area 52 (see FIG. 10). This allows the user to know man-hours that are required when a change, etc., of main function design or safety design arises, and therefore facilitates adjustment of a development schedule.

FIG. 10 is an example of a display screen related to main function design and safety design in the safety design support system (see also FIG. 9 when necessary).

In the example of FIG. 10, values of work scales (man-hours) required for design work are displayed such that each value is associated with each of items in the “component” of main function design and with each of items in the “technical level safety requirement” of safety design as well. In other words, items of the function design information and items of the safety design information 62 include items with which values of work scales of design work are associated, respectively. These values of work scales are set by the user's operation on the input unit 11 (see FIG. 1).

For example, a case is assumed where the item of “obstacle detection” in the “function” is changed in a given manner by the user's operation on the input unit 11 (see FIG. 1). Based on a tracking relationship between items and on a work scale of each item, the man-hour estimating unit 30 (see FIG. 9) extracts items having a direct or indirect tracking relationship with the item “obstacle detection” and calculates the sum of work scales of the items. In the example of FIG. 10, a plurality of items are extracted, which consists of the “control controller” and “obstacle sensor” included in the “component”, the “detection function problem detection” included in the “function level safety requirement”, and the “sensor problem detection” and “stop command output” included in the “technical level safety requirement”. No work scale value is set for each of items making up the “function level safety requirement”.

The man-hour estimating unit 30 (see FIG. 9) calculates the sum of work scales of the extracted items (see a “man-hour” column in FIG. 10), as the value of man-hours (e.g., 12 man-hours) required for reviewing the product design. Then, the man-hour estimation output unit 22g (see FIG. 9) displays the value of man-hours estimated by the man-hour estimating unit 30, in the guide display area 52. In the example of FIG. 10, “Estimated correction man-hours required as a result of change of function F-3: 12 man-hours” is displayed in the guide display area 52.

In this manner, when an item of the main function design information 61 is changed or added, the man-hour estimation output unit 22g (display control unit) causes the display unit 12 (display means: see FIG. 1) to display man-hours required for changing the product design, based on work scale values associated with other items having a direct or indirect tracking relationship with the item. The user is thus able to know how many man-hours are required to correct the product design as a result of change of the item of “obstacle detection”.

The above method of calculating man-hours is an example, that is, man-hours calculation methods are not limited to this method. For example, the man-hours may be calculated by multiplying the above sum of work scales by a given factor, or the man-hours may be calculated by another method.

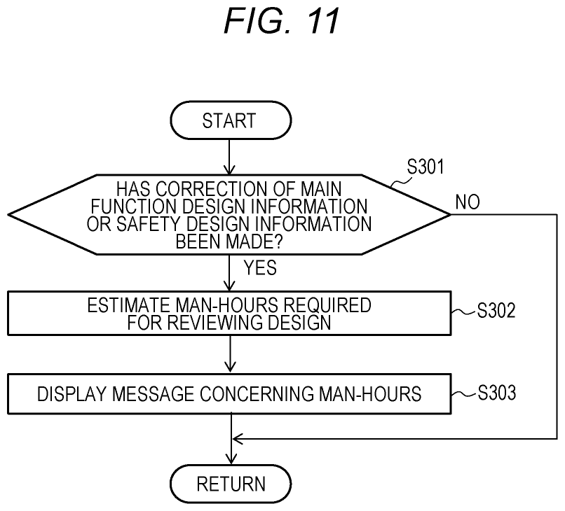

FIG. 11 is a flowchart showing processing in the safety design support system (see also FIG. 9).

It is assumed that at the point of “START” in FIG. 11, each process is already defined (set). At step S301, the safety design support system 100B causes the correction determining unit 29 to determine whether correction (change or addition) of the main function design information 61 or the safety design information 62 has been made. When it is determined at step S301 that correction of the main function design information 61 or the safety design information 62 has been made (S301: Yes), the safety design support system 100B proceeds to step 5302.

At step S302, the safety design support system 100B causes the man-hour estimating unit 30 to estimate man-hours required for reviewing product design.

At step S303, the safety design support system 100B causes the man-hour estimation output unit 22g to display a message concerning the man-hours (see the guide display area 52 in FIG. 10). After executing step S303, the safety design support system 100B returns to “START” (RETURN).

When it is determined at step S301 that correction of the main function design information 61 or the safety design information 62 has not been made (S301: NO), the safety design support system 100B returns to “START” (RETURN). A series of steps shown in FIG. 11 are repeated every time correction (change or addition) of the main function design information 61 is made.

### Effects

According to the third embodiment, when correction (change or addition) of the main function design information 61 or the safety design information 62 is made, the man-hours required for reviewing the product design are estimated, based on a tracking relationship between items and work scales of individual items. This allows the user to know how many man-hours are required when the main function design information 61 or the safety design information 62 are corrected. In addition, even when the product is complex and large-scale, the man-hours required for reviewing the product design can be calculated properly, based on a tracking relationship between items and work scales of individual items.

### Modification

The safety design support system 100 and the like according to the present invention have been described in the above embodiments. The present invention, however, is not limited to the description of these embodiments and may be modified into various forms.

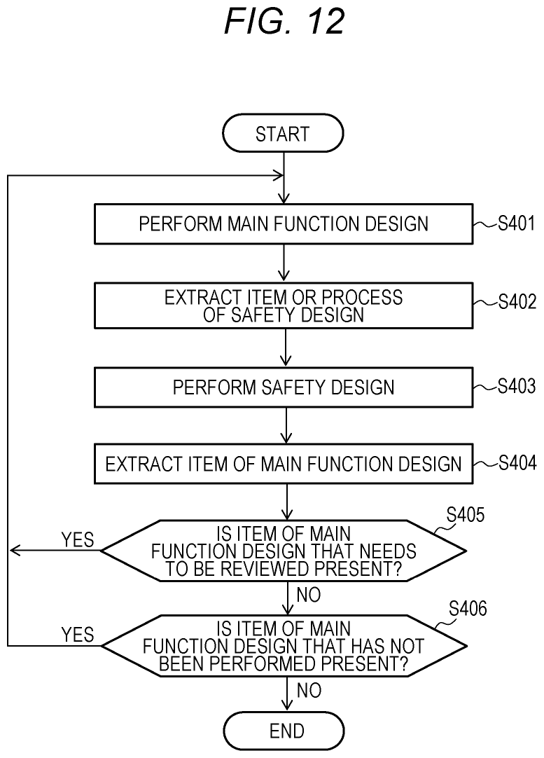

For example, the safety design support system 100 may execute a series of steps shown in FIG. 12 in a configuration in which the first embodiment and the second embodiment are combined together.

FIG. 12 is a flowchart showing processing in a safety design support system according to a modification

It should be noted that steps S401 to S403 in FIG. 12 corresponds to the first embodiment (see FIG. 5), and steps S404 to S406 correspond to the second embodiment (see FIG. 8).

At step S401, the safety design support system 100 performs main function design. Specifically, the safety design support system 100 receives input of the main function design information 61 by the user's operation on the input unit 11 (see FIG. 1).

At step S402, the safety design support system 100 extracts an item or process of safety design. In other words, the safety design support system 100 extracts an item, etc., of safety design to be performed at the next step S403, based on a tracking relationship between the item and the item of the main function design information 61 that has been inputted at step S401. Although not shown in FIG. 12, the safety design support system 100 may cause the display unit to display given instruction information on review of safety design after step S403.

Subsequently, at step S403, the safety design support system 100 performs safety design. For example, the safety design support system 100 receives input of the safety design information 62 by the user's operation on the input unit 11 (see FIG. 1). According to such processing, every time the main function design information 61 is inputted, an item, etc., of the safety design information 62 that is to be reviewed next is extracted. The user is, therefore, able to proceed with safety design efficiently. At step S403, the safety design executing unit 27 (see FIG. 6) may create the safety design information 62 in place of the user's creating the safety design information 62 by an input operation.

Subsequently, at step S404, the safety design support system 100 extracts an item of main function design that needs to be reviewed. Specifically, the safety design support system 100 extracts an item of main function design that needs to be reviewed, based on a tracking relationship between the item and an item of the safety design information 62 that has been inputted at step S403.

At step S405, the safety design support system 100 determines whether an item of main function design that needs to be reviewed is present. When an item of main function design that needs to be reviewed is present (S405: Yes), the safety design support system 100 returns to step S401. When an item of main function design that needs to be reviewed is present (S405: Yes), the safety design support system 100 may cause the display unit to display given instruction information on review of main function design and then return to step S401.

When, in Step S404, an item of main function design that needs to be reviewed is not present (S405: NO), the safety design support system 100 proceeds to step S406.

At step S406, the safety design support system 100 determines whether an item of main function design that has not been performed is present. Whether an item having not been performed is present may be determined by the user. When an item of main function design that has not been performed is present (S406: Yes), the safety design support system 100 returns to step S401. When an item of main function design that has not been performed is not present (S406: NO), the safety design support system 100 ends a series of steps (END). By performing such processing, an item of main function design that needs to be reviewed can be identified according to change or addition of an item of safety design. The user is, therefore, able to efficiently proceed with product design. In addition, by proceeding with main function design and safety design simultaneously, a product development period can be shortened.

In each embodiment, the case where “required specifications”, “function”, and “component” are hierarchically ordered as processes of main function design (see FIG. 4) has been described. The name and content of each process, however, may be changed when necessary. This statement applies also to each of processes of safety design (see FIG. 4).

In the second embodiment, the case where the safety design executing unit 27 creates the safety design information 62 has been described, but creation of the safety design information 62 is not limited to this case. For example, in the safety design information 62, the “safety target” etc., ranked higher in the hierarchical order may be inputted by the user's operation on the input unit 11 (see FIG. 1) while the remaining safety design information 62 may be created by the safety design executing unit 27.

In a configuration in which, for example, the second embodiment and the third embodiment are combined and the safety design executing unit 27 generates the safety design information 62, when the main function design information 61 is changed or added by the user's input operation, man-hours required for reviewing the product design may be displayed.

A program of a safety design support method executed by the safety design support system can be provided via a communication line or can be distributed as a program written to a recording medium, such as a CD-ROM.

Each of the above embodiments has been described in detail for easy understanding of the present invention, and is not necessarily limited to an embodiment including all the constituent elements described above. Some of constituent elements of the embodiment can be deleted therefrom or add to or replaced with constituent elements of another embodiment. A group of mechanisms and constituent elements considered to be necessary for description are described above, and all mechanisms and constituent elements making up the product are not necessarily illustrated.

What is claimed is:

1. A safety design support system comprising a display control unit that causes a display means to display main function design information, in which items related to a main function of a product to be designed are hierarchically ordered, and safety design information, in which items related to safety design of the product are hierarchically ordered,
wherein in accordance with change or addition of an item of the main function design information, the change or addition being made by a user's input operation, the display control unit causes the display means to display instruction information that prompts the user to carry out a next input operation.

2. The safety design support system according to claim 1, wherein when an item of the main function design information is changed or added, the display control unit causes the display means to display the instruction information that instruct the user to review an item of the safety design information, the item having a direct or indirect tracking relationship with the changed or added item of the main function design information.

3. The safety design support system according to claim 2, wherein when an item of the safety design information is inputted by a user's input operation after the instruction information is displayed and, among items of the safety design information to be reviewed, an item that has not been changed or added remains, the display control unit causes the display means to display a predetermined message.

4. The safety design support system according to claim 1, comprising a safety design executing unit that creates the safety design information, based on the main function design information,
wherein when an item of the main function design information is changed or added, the display control unit causes the display means to display the instruction information that instruct the user to review an item of the main function design information, the item having a direct or indirect tracking relationship with an item of the safety design information that has been newly created as a result of the change or addition of the item of the main function design information.

5. The safety design support system according to claim 1,
wherein items of the main function design information and items of the safety design information include an item with which a value of a design work scale is associated, and
wherein when an item of the main function design information is changed or added, the display control unit causes the display means to display man-hours required for changing design of the product, based on the value of the design work scale associated with a different item having a direct or indirect tracking relationship with the item.

6. The safety design support system according to claim 2,
wherein items of the main function design information and items of the safety design information include an item with which a value of a design work scale is associated, and
wherein when a plurality of items having a direct or indirect tracking relationship with the item of the main function design information that has been changed or added are present, the display control unit causes the display means to display the instruction information so that the items are reviewed in descending order of the value of the design work scale.

7. The safety design support system according to claim 2, wherein when a plurality of items having a direct or indirect tracking relationship with the item of the main function design information that has been changed or added are present, the display control unit causes the display means to display the instruction information so that the items are reviewed in descending order of a number of tracking relationships with a different item.

8. A safety design support method comprising:
a first display processing of causing a display means to display main function design information in which items related to a main function of a product to be designed are hierarchically ordered, and safety design information in which items related to safety design of the product are hierarchically ordered; and
a second display processing of causing the display means to display instruction information that prompts a user to carry out a next input operation, in accordance with change or addition of an item of the main function design information, the change or addition being made by the user's input operation.
